(19) United States
(12) Patent Application Publication
(10) Pub. No.: US 2024/0258230 A1
(43) Pub. Date: Aug. 1, 2024

(54) SEMICONDUCTOR DEVICES

(71) Applicant: Samsung Electronics Co., Ltd., Suwon-si (KR)

(72) Inventors: Sungkeun Lim, Suwon-si (KR); Dohyun Go, Suwon-si (KR); Unki Kim, Suwon-si (KR); Hyohoon Byeon, Suwon-si (KR); Yuyeong Jo, Suwon-si (KR); Jinyeong Joe, Suwon-si (KR)

(21) Appl. No.: 18/515,463

(22) Filed: Nov. 21, 2023

(30) Foreign Application Priority Data
Jan. 30, 2023 (KR) 10-2023-0011727

(51) Int. Cl. H01L 23/522; H01L 21/768; H01L 23/29; H01L 23/31

(52) U.S. Cl. CPC H01L 23/5226; H01L 21/76898; H01L 23/291; H01L 23/3171

(57) ABSTRACT

A semiconductor device includes a substrate; an active region extending on the substrate in a first direction; a protective layer on a lower surface of the substrate; an etch stop layer on a lower surface of the protective layer; a device isolation layer defining the active region; a gate structure on the active region and extending in a second direction, intersecting the first direction; a source/drain region on the active region on both lateral sides of the gate structure; a contact structure connected to the source/drain region; and a power transmission structure electrically connected to the contact structure.

### CROSS-REFERENCE TO RELATED APPLICATION(S)

This application claims the benefit of priority to Korean Patent Application No. 10-2023-0011727 filed on Jan. 30, 2023, in the Korean Intellectual Property Office, the subject matter of which is hereby incorporated by reference in its entirety.

### BACKGROUND

The present inventive concept relates to a semiconductor device.

In various semiconductor devices such as a logic circuit and a memory, a source region and a drain region may be connected to interconnections of a back-end-of-line (BEOL) through a contact plug. Meanwhile, with higher integration of semiconductor devices, a backside power distribution network (BSPDN) may be provided in which interconnections are disposed on a rear surface of a substrate opposite to a front surface of the substrate.

### SUMMARY

An aspect of the present inventive concept is to provide a semiconductor device having improved electrical characteristics.

According to an aspect of the present inventive concept, a semiconductor device includes a substrate; an active region extending on a substrate in a first direction; a protective layer on a lower surface of the substrate; an etch stop layer on a lower surface of the protective layer; a device isolation layer defining the active region; a gate structure on the active region and extending in a second direction, intersecting the first direction; a source/drain region on the active region on both lateral sides of the gate structure; a contact structure connected to the source/drain region; and a power transmission structure electrically connected to the contact structure.

According to an aspect of the present inventive concept, a semiconductor device includes a substrate; an active region extending on a substrate in a first direction; a plurality of channel layers on the active region to be spaced apart from each other in a vertical direction, perpendicular to an upper surface of the substrate; a device isolation layer defining the active region; a gate structure on the active region and extending in a second direction, intersecting the first direction; a source/drain region on the active region on both lateral sides of the gate structure; a contact structure connected to the source/drain region; a buried conductive structure connected to the contact structure; a lower interlayer insulating layer on a lower surface of the substrate; and a power transmission structure passing through the lower interlayer insulating layer and connected to the buried conductive structure, wherein at least a portion of the active region and the plurality of channel layers includes a group 13 element or a group 15 element of the periodic table of elements in a first concentration, and at least a portion of the active region and the plurality of channel layers includes a carbon (C) element or an oxygen (O) element in a second concentration.

According to an aspect of the present inventive concept, a semiconductor device includes a substrate; an active region extending on a substrate in a first direction; a protective layer on a lower surface of the substrate, including silicon (Si) or silicon germanium (SiGe), and including at least one of a carbon (C) element or an oxygen (O) element; a device isolation layer defining the active region; a gate structure on the active region and extending in a second direction, intersecting the first direction; a source/drain region on the active region on both lateral sides of the gate structure; a contact structure connected to the source/drain region; and a power transmission structure electrically connected to the contact structure, wherein the active region includes at least one of the carbon (C) element or the oxygen (O) element, and a concentration of the carbon (C) element or a concentration of the oxygen (O) element in the protective layer is higher than a concentration of the carbon (C) element or the oxygen (O) element in the active region.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to example embodiments.

FIG. 2A is a cross-sectional view illustrating a semiconductor device according to example embodiments.

FIG. 2B illustrates concentration distributions of a first element and a second element in a channel region in a semiconductor device according to example embodiments.

FIG. 2C illustrates concentration distributions of a first element and a second element in a channel region in a semiconductor device according to example embodiments.

FIG. 3A is a cross-sectional view illustrating a semiconductor device according to example embodiments.

FIG. 3B illustrates concentration distributions of a first element and a second embodiments.

FIG. 3C illustrates concentration distributions of a first element and a second element in a channel region in a semiconductor device according to example embodiments.

FIG. 4A is a cross-sectional view illustrating a semiconductor device according to example embodiments.

FIG. 4B illustrates concentration distributions of a first element and a second element in a channel region in a semiconductor device according to example embodiments.

FIG. 4C illustrates concentration distributions of a first element and a second element in a channel region in a semiconductor device according to example embodiments.

FIGS. 5 to 8 are views illustrating a process sequence of a method of manufacturing a semiconductor device according to example embodiments.

### DETAILED DESCRIPTION

Hereinafter, with reference to the accompanying drawings, embodiments of the present inventive concept will be described as follows.

As used herein, the terms “integrally formed” may refer to structures, patterns, and/or layers that are formed at the same time and of the same material, without a break in the continuity of the material of which they are formed. As one example, structures, patterns, and/or layers that are “integrally formed” may be homogeneous monolithic structures. The term “buried” may refer to structures, patterns, and/or layers that are formed at least partially below a top surface of another structure, pattern, and/or layer. In some embodiments, when a first structure, pattern, and/or layer is “buried” in a second structure, pattern, and/or layer, the second structure, pattern, and/or layer may surround at least a portion of the first structure, pattern, and/or layer. For example, a first structure, pattern, and/or layer first may be considered to be buried when it is at least partially embedded in a second structure, pattern, and/or layer.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Thickness may refer to the thickness or height measured in a direction perpendicular to a top surface of the substrate.

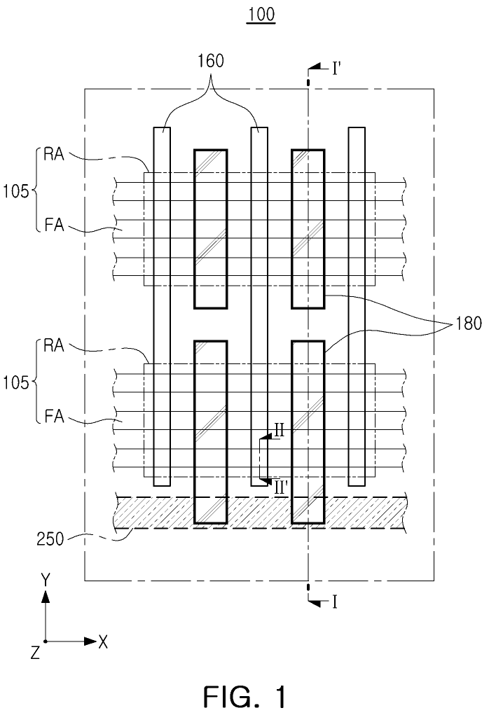

FIG. 1 is a plan view illustrating a semiconductor device according to example embodiments.

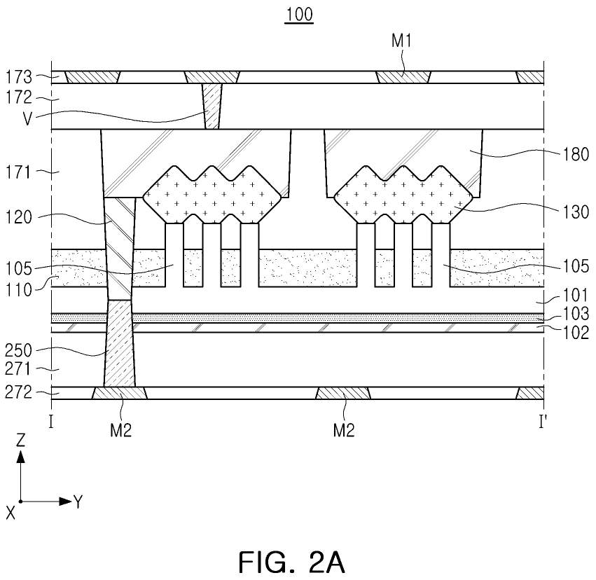

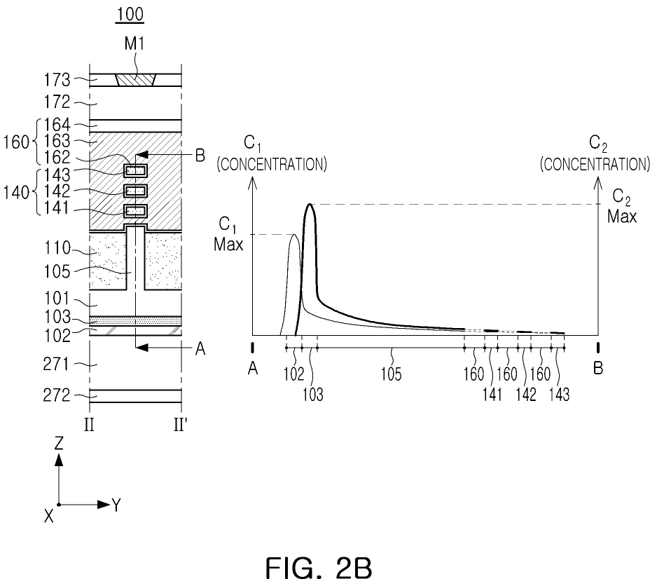

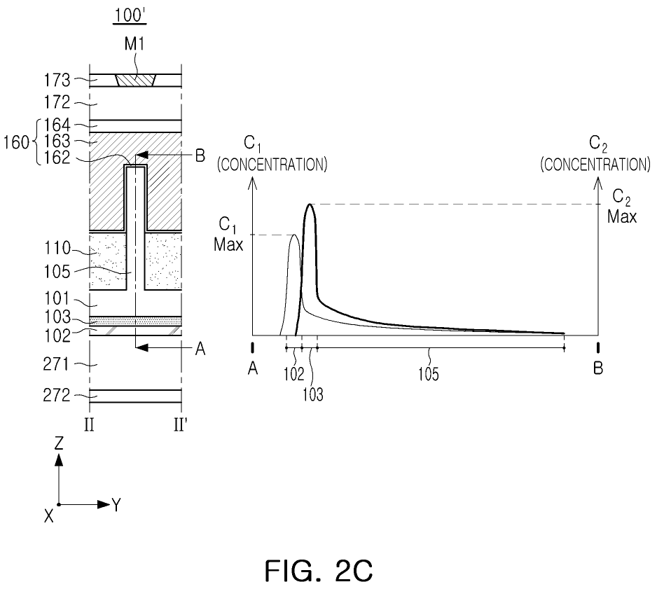

FIG. 2A is a cross-sectional view illustrating a semiconductor device according to example embodiments. FIG. 2A is a cross-sectional view of the semiconductor device of FIG. 1, taken along line I-I′.

FIG. 2B illustrates concentration distributions of a first element and a second element in a channel region in a semiconductor device according to example embodiments. FIG. 2B is a cross-sectional view of the semiconductor device of FIG. 1, taken along line II-II′, and illustrates distributions of a first concentration C₁ of the first element and a second concentration C₂ of the second element in an etch stop layer 102, a protective layer 103, an active region 105, and a plurality of channel layers 141, 142, and 143, taken along line A-B in FIG. 2B. In a graph of FIG. 2B, a horizontal axis represents a depth (e.g., location relative to A) from A to B, and a vertical axis represents a first concentration C₁ (indicated by the relatively thinner line of the graph) of the first element and a second concentration C₂ (indicated by the relatively thicker line of the graph) of the second element. The graph of FIG. 2B illustrates distributions of the first concentration C₁ of the first element and the second concentration C₂ of the second element.

In the following description, the reference may be made to the concentrations C₁ and C₂ or the elements not being measurable. Unless otherwise indicated by the context, the phrase “may not be measurable” refers to a concentration being too low to measure, a concentration being too low to detect the element being measured, or the element being absent. For example, as the concentration of an element approaches zero it may be too difficult to measure the concentration or detect the element event though a measurement may be attempted.

Referring to FIGS. 1 to 2B, a semiconductor device 100 according to example embodiments may include a substrate 101, an active region 105 on the substrate 101, a protective layer 103 disposed on a lower surface of the substrate 101, an etch stop layer 102 disposed on a lower surface of the protective layer 103, a device isolation layer 110 defining the active region 105, a gate structure 160 disposed on the active region 105, a source/drain region 130 disposed on the active region 105 on both lateral sides (e.g., two sides spaced apart in the X direction as shown in the figures) of the gate structure 160, a contact structure 180 connected to the source/drain region 130, a buried conductive structure 120 connection connected to the contact structure 180, and a power transmission structure 250 connected to the buried conductive structure 120. The semiconductor device may further include a channel structure 140 including a plurality of channel layers 141, 142, and 143 disposed vertically spaced apart from each other on the active region 105, first to third upper interlayer insulating layers 171, 172 and 173, first and second lower interlayer insulating layers 271 and 272, a via V, and first and second interconnection portions M1 and M2.

The substrate 101 may be formed of and/or include a semiconductor material, such as a group IV semiconductor, a group III-V compound semiconductor, or a group II-VI compound semiconductor. For example, the group IV semiconductor may include silicon (Si), germanium (Ge), or silicon germanium (SiGe). The substrate 101 may be provided as a bulk wafer, an epitaxial layer, a silicon-on-insulator (SOI) layer, a semiconductor-on-insulator (SeOI) layer, or the like.

The active region 105 may include a base active region RA and an active fin FA. The active fin FA may be defined or limited by the device isolation layer 110 in the substrate 101, and may extend lengthwise in an X direction (e.g., a first horizontal direction). The active fin FA may protrude from the base active region RA, and may have a fin structure. The active fin FA may protrude upward from the base active region RA in a direction perpendicular to a major surface of the substrate 101 (e.g., a vertical or Z direction). The active fin FA may include two impurities. A plurality of active fins FA may be disposed spaced apart from each other in a Y direction (e.g., a second horizontal direction which may be perpendicular to the first horizontal direction). According to an example embodiment, the active region 105 may include a carbon (C) element or an oxygen (O) element in a second concentration C₂, and the active region may include a group 13 element or a group 15 element of the periodic table of elements in a first concentration C₁. According to an example embodiment, the group 13 element of the periodic table of elements may be boron (B).

The protective layer 103 may be disposed on the lower surface of the substrate 101. The protective layer 103 may be formed on a base substrate 101′, to be described later, by an epitaxial growth process, and may be formed of and/or include silicon (Si) or silicon germanium (SiGe). According to an example embodiment, the protective layer 103 may further include at least one of a carbon (C) element or an oxygen (O) element to prevent impurities in the etch stop layer 102 from diffusing into the substrate 101, the active region 105, and/or the channel structure 140. Specifically, the protective layer 103 may include at least one of SiC or SiO, having a low acid coefficient. The protective layer 103 may be disposed between the substrate 101 and the first lower interlayer insulating layer 271. The protective layer 103 may be disposed between the substrate 101 and the etch stop layer 102.

In this specification, ‘a carbon (C) element or an oxygen (O) element’ included in the protective layer 103 may be referred to as a ‘second element,’ and ‘impurities’ included in the etch stop layer 102 may be referred to as a ‘first element.’

As illustrated in FIG. 2B, a second concentration C₂ of a carbon (C) element or a concentration of an oxygen (O) element in the protective layer 103 may be higher than a second concentration C₂ of a carbon (C) element or a concentration of an oxygen (O) element in the active region 105. The second concentration C₂ of the carbon (C) element or the concentration of the oxygen (O) element in the protective layer 103 may be higher than a second concentration C₂ of a carbon (C) element or a concentration of an oxygen (O) element in the plurality of channel layers 141, 142, and 143. According to an example embodiment, the second concentration C₂ of the second element may have a distribution having a peak in a section in which the protective layer 103 exists (e.g., a peak concentration in the protective layer 103). The second concentration C₂ of the second element may decrease at locations approaching an upper portion in the plurality of channel layers 141, 142, and 143. For example, the second concentration C₂ of the second element may decrease from a location in a first channel layer 141 to a location in a third channel layer 143. The second concentration C₂ of the second element in the upper portion in the plurality of channel layers 141, 142, and 143 may be close to 0, and the second element may not be measurable, but is not limited thereto. According to an example embodiment, the second element may not be measurable in the gate structure 160 between the plurality of channel layers 141, 142, and 143.

The etch stop layer 102 may be disposed on the lower surface of the protective layer 103. The etch stop layer 102 may be disposed between the protective layer 103 and the first lower interlayer insulating layer 271. The etch stop layer 102 may be formed on a base substrate 101′, to be described later, by an epitaxial growth process, and may be formed of and/or include silicon (Si) or silicon germanium (SiGe). The etch stop layer 102 may be a highly doped region, as compared to the base substrate 101′ described later, and may thus have etch selectivity with respect to the base substrate 101′. The etch stop layer 102 may have an impurity concentration higher than an impurity concentration of the base substrate 101′. According to an example embodiment, the etch stop layer 102 may include impurities in a concentration ranging from about 1×10¹⁹ atoms/cm³ or higher to about 1×10²² atoms/cm³. For example, the etch stop layer 102, which may be highly doped, may be disposed on the base substrate 101′.

Conventionally, an upper layer on a base substrate 101′ may be doped in a lower concentration than a lower layer below the base substrate 101′. Therefore, in a process of etching a base substrate 101′, to be described later, a with-in-wafer (WiW) thickness variation (i.e., a variation within a wafer in contrast to wafer-to-wafer (WTW) thickness variation) in a remaining thickness of the base substrate 101′ may occur. Next, when a process of forming a power transmission structure 250, to be described later, is performed, there may be a problem in that a defect in the power transmission structure 250 occurs due to the with-in-wafer (WiW) thickness variation. In the present inventive concept, since the etch stop layer 102 may have an impurity concentration higher than an impurity concentration of the base substrate 101′, a variation in the with-in-wafer (WiW) thickness of the etch stop layer 102 that remains after etching the base substrate 101′ may be reduced.

The impurities of the etch stop layer 102 may include at least one of phosphorus (P), arsenic (As), antimony (Sb), boron (B), gallium (Ga), aluminum (Al), thallium (Tl), or indium (In). The etch stop layer 102 may be formed of and/or include a group 13 element or a group 15 element of the periodic table of elements. According to an example embodiment, the group 13 element of the periodic table of elements may be boron (B). For example, the etch stop layer 102 may be a P+ region in which P-type impurities are doped in a high concentration. However, the present inventive concept is not limited thereto, and the etch stop layer 102 may be an N+ region in which N-type impurities are doped in a high concentration.

As illustrated in FIG. 2B, the first concentration C₁ of the first element (e.g., an impurity) in the etch stop layer 102 may be higher than the first concentration C₁ of the first element in the active region 105. The first concentration C₁ of the first element in the etch stop layer 102 may be higher than the first concentration C₁ of the first element in each of the plurality of channel layers 141, 142, and 143. According to an example embodiment, the first concentration C₁ of the first element may have a distribution having a peak in a section in which the etch stop layer 102 exists (e.g., a peak concentration within the etch stop layer 102). The protective layer 103, which includes the second element, may serve to prevent diffusion of the first element (e.g., diffusion of the first element into the active region 105) and thus the first concentration C₁ of the first element may have a rapidly decreasing distribution in the section of the protective layer 103. The first concentration C₁ of the first element may decrease toward an upper portion in the plurality of channel layers 141, 142, and 143. For example, the first concentration C₁ of the first element may decrease from the first channel layer 141 to the third channel layer 143. The first concentration C₁ of the first element in the upper portion in the plurality of channel layers 141, 142, and 143 may be close to 0, and the first concentration of the first element may not be measurable, but is not limited thereto. According to an example embodiment, the first element may not be measurable in the gate structure 160 between the plurality of channel layers 141, 142, and 143. According to an example embodiment, the second concentration C₂ of the second element may be higher than the first concentration C₁ of the first element throughout the semiconductor 100 or within a portion of the semiconductor 100 such as the gate structure 160, but is not limited thereto. In the drawings, the first concentration C₁ of the first element and the second concentration C₂ of the second element do not show relative sizes. The first concentration C₁ of the first element and the second concentration C₂ of the second element may be measured by a time-of-flight secondary ion mass spectrometry (ToF-SIMS), and concentrations of impurities such as boron (B), carbon (C), and oxygen (O) in the etch stop layer 102, the protective layer 103, the substrate 101, the active region 105, and the like may be compared. According to an example embodiment, the first element may not be measurable in the gate structure 160 between the plurality of channel layers 141, 142, and 143.

The device isolation layer 110 may define the active region 105 in the substrate 101 (e.g., lateral or vertical surfaces of the device isolation layer 110 may be coplanar with lateral or vertical surfaces of the active region). The device isolation layer 110 may include, for example, a first portion formed by a shallow trench isolation (STI) process which may include a lateral surface defining a portion of the active fin FA, and a second portion formed by a deep trench isolation (DTI) process which may include a lateral surface defining a portion of the base active region RA. The second portion may extend deeper into the substrate 101, as compared to the first portion. The device isolation layer 110 may be formed of and/or include, for example, a silicon oxide-based insulating material or a silicon nitride-based insulating material, and may be, specifically, a tetra ethyl ortho silicate (TEOS), an undoped silicate glass (USG), a phosphosilicate glass (PSG), a borosilicate glass (BSG), a borophosphosilicate glass (BPSG), a fluoride silicate glass (F/SG), a spin-on-glass (SOG), a Tonen silazene (TOSZ), or a combination thereof.

The gate structure 160 may cover a portion of the active fin FA of the active region 105. A channel region of a transistor may be formed where the active fin FA crosses the gate structure 160. The gate structure 160 may include a gate dielectric layer 162, a gate electrode 163, and a gate capping layer 164 on an upper surface of the gate electrode 163. Although not illustrated, the gate structure 160 may be electrically connected to the first interconnection portion M1.

The gate dielectric layer 162 may be disposed between the active fin FA and the gate electrode 163. The gate dielectric layer 162 may be formed of and/or include an oxide, a nitride, or a high-K material. The high-κ material may refer to a dielectric material having a dielectric constant, higher than a dielectric constant of silicon oxide (SiO₂). The high-K material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The gate electrode 163 may be spaced apart from the active fin FA by the gate dielectric layer 162. The gate electrode 163 may be formed of and/or include a conductive material, and may include, for example, a metal nitride such as titanium nitride (TiN), tantalum nitride (TaN), or tungsten nitride (WN), and/or a metal material such as aluminum (Al), tungsten. (W), molybdenum (Mo), or the like, or a semiconductor material such as doped polysilicon. The gate electrode 163 may be provided as two or more multilayer structures. The gate electrode 163 may be electrically insulated from the source/drain regions 130 through spacer layers.

The source/drain regions 130 may serve as a source region or a drain region of a transistor. The source/drain regions 130 may be connected to the active regions 105, respectively. The source/drain regions 130 may be a semiconductor layer formed of and/or including silicon (Si), or may be provided as an epitaxial layer. The source/drain regions 130 may include impurities. For example, the source/drain regions 130 may include n-type doped silicon (Si) or p-type doped silicon germanium (SiGe). The source/drain regions 130 may include a plurality of regions including different concentrations of elements and/or doping elements. In another example, the source/drain regions 130 may have a merged shape in the Y direction (e.g., a second horizontal direction).

The contact structures 180 may be disposed on the source/drain regions 130. The contact structures 180 may pass vertically through a top surface of the first upper interlayer insulating layer 171, and may be connected to the source/drain regions 130.

The contact structures 180 may have side surfaces inclined such that the width of each of the contact structures 180 decreases from a top surface of the contact structure 180 towards the substrate 101 due to an aspect ratio, but embodiments are not limited thereto. The contact structures 180 may be disposed to contact upper surfaces of the source/drain regions 130. In some embodiments, the source/drain region 130 may have a smooth upper surface without recesses that contacts the contact structures 180. Separate gate contact structures may be further disposed on the gate electrodes 163 in a region not illustrated.

Each of the contact structures 180 may include a metal silicide layer located on a lower end thereof, and may further include a barrier layer disposed on the metal silicide layer and sidewalls. The barrier layer may be formed of and/or include, for example, a metal nitride such as titanium nitride (TiN), tantalum nitride (TaN), or tungsten nitride (WN). The contact structures 180 may be formed of and/or include, for example, a metal material such as aluminum (Al), tungsten (W), molybdenum (Mo), or the like. In example embodiments, the number and arrangement of conductive layers constituting the contact structures 180 may be variously changed.

The buried conductive structure 120 may be disposed adjacent to the active region 105 and may be horizontally spaced apart from the active region 105 with a portion of the device isolation layer 110 disposed between the active region 105 and the buried conductive structure 120 and/or a portion of the first upper isolating layer 171 disposed between the active region 105 and the buried conductive structure 120. The buried conductive structure 120 may pass through the device isolation layer 110, and may extend deeper (e.g., penetrate) into the substrate 101, as compared to the device isolation layer 110. For example, a lower surface of the buried contact structure 120 may be at a lower vertical level than a lower surface of the device isolation layer 110. In some examples, the buried conductive structure 120 may be disposed between active regions 105 which may be adjacent to each other.

The buried conductive structure 120 may be connected to the contact structure 180, and may be connected to the power transmission structure 250. The buried conductive structure 120 may receive a power voltage from the power transmission structure 250, and may serve as an electrical path for supplying the power voltage to devices through the contact structures 180. In some embodiments, the buried conductive structure 120 may be integrally formed with the contact structure 180.

The buried conductive structure 120 may include a conductive layer and a barrier layer surrounding the conductive layer, the barrier layer may be formed of and/or include a metal compound such as titanium nitride (TiN), tantalum nitride (TaN), or tungsten nitride (WN), and the conductive layer may be formed of and/or include, for example, a metal material such as tungsten (W), titanium (Ti), aluminum (Al), or copper (Cu). In an example embodiment, insulating spacer layers may be disposed on a side surface of the buried conductive structure 120 to electrically separate the buried conductive structure 120 from other elements such as another buried conductive structure 120, the substrate 101, and/or the power transmission structure 250.

The power transmission structure 250 may pass through the protective layer 103 and the etch stop layer 102, and may be connected to the buried conductive structure 120. The power transmission structure 250 may pass through the first lower interlayer insulating layer 271. The power transmission structure 250 may be in contact with the buried conductive structure 120 and the substrate 101, but embodiments are not limited thereto. The power transmission structure 250 and the buried conductive structure 120 may be in contact with each other within the substrate 101, the device isolation layer 110, or the first upper interlayer insulating layer, according to a process. For example, a lower surface of the buried conductive structure 120 may contact an upper surface of the power transmission structure 250. The power transmission structure 250 may be provided as a path for supplying necessary power to device regions (e.g., source/drain regions 130) implemented on the substrate 101. In an example embodiment, insulating spacer layers may be disposed on a side surface of the power transmission structure 250 to electrically separate the power transmission structure 250 from other elements such as other power transmission structures 250 and the substrate 101.

The channel structure 140 may include the plurality of channel layers 141, 142, and 143. In the semiconductor device 100, the active region 105 may have a fin structure, and the gate electrode 163 may be provided between the active region 105 and the channel structure 140, between each of the plurality of channel layers 141, 142, and 143 of the channel structures 140, and on the channel structure 140. Therefore, the semiconductor device 100 may include a gate-all-around type field effect transistor including the channel structure 140, the source/drain region 130, and the gate structure 160, e.g., a multi bridge channel FET (an MBCFET™).

The plurality of channel layers 141, 142, and 143 may include three or more plural layers spaced apart from each other in a vertical direction (e.g., a Z-direction) which is perpendicular to an upper surface of the active fin FA. The plurality of channel layers 141, 142, and 143 may be connected to the source/drain regions 130. The plurality of channel layers 141, 142, and 143 may be formed of and/or include a semiconductor material, and may include, for example, at least one of silicon (Si), silicon germanium (SiGe), or germanium (Ge). The plurality of channel layers 141, 142, and 143 may be formed of and/or include the same material as the substrate 101, for example. The number and shapes of the plurality of channel layers 141, 142, and 143 constituting one channel structure may be variously changed in embodiments.

At least a portion of the plurality of channel layers 141, 142, and 143 may include at least one of a carbon (C) element or an oxygen (O) element, included in the protective layer 103.

At least a portion of the plurality of channel layers 141, 142, and 143 may include impurities that may be the same as the impurities included in the etch stop layer 102 in a high concentration. According to an example embodiment, at least a portion of the plurality of channel layers 141, 142, and 143 may include boron (B) as an impurity.

The first to third upper interlayer insulating layers 171, 172, and 173 and the first and second lower interlayer insulating layers 271 and 272 may be formed of and/or include at least one of oxide, a nitride, or an oxynitride. For example, a low-K material may be included. The first lower interlayer insulating layer 271 may be disposed on the lower surface of the etch stop layer 102. The first to third upper interlayer insulating layers 171, 172, and 173 and the first and second lower interlayer insulating layers 271 and 272 may be formed of the same material or may be formed of different materials.

The via V may pass through the second upper interlayer insulating layer 172. The via V may be connected to the contact structures 180. The via V may be formed of and/or include a conductive material.

The first interconnection portion M1 and the via V may constitute a back-end-of-line (BEOL). The second interconnection portion M2 may be an interconnection portion for power transmission, and the first interconnection portion M1 and the via V may be provided as interconnection portions for signal transmission. According to an example embodiment, a signal transmission network may be configured to be connected from the first interconnection portion M1 and the via V to a device region (e.g., the source/drain region 130 and the gate electrode 163) through the contact structure 180. A power transmission network may be configured to be connected from the second interconnection portion M2 to a device region (e.g., the source/drain region 130) through the substrate 101.

In the description of the following embodiments, elements and descriptions that would be the same as those described above may be omitted.

FIG. 2C illustrates a first concentration C₁ distribution of a first element (e.g., a carbon (C) element or an oxygen (O) element included in the protective layer 103) and a second concentration C₂ distribution of a second element (e.g., impurities included in the etch stop layer 102) in a channel region in a semiconductor device according to example embodiments. FIG. 2C may correspond to a cross-sectional view of the semiconductor device of FIG. 1, taken along line II-II′, and illustrates the first concentration C₁ of the first element and the second concentration C₂ of the second element in an etch stop layer 102, a protective layer 103, and an active region 105, taken along line A-B.

Referring to FIGS. 1 and 2C, an active region 105 may include a base active region RA and at least one active fin FA, and the at least one active fin FA may protrude upward (e.g., in the Z-direction shown in the figures) from the base active region RA, and may extend in a first lateral direction (the X-direction).

A semiconductor device 100′ may include FinFET devices in which the active region 105 is a transistor having a fin structure. The FinFET devices may include transistors arranged around the active region 105 and a gate structure 160. The transistors may be located where the active region 105 and the gate structure 160 cross over one another as viewed in a plan view. For example, the transistors may be NMOS transistors or PMOS transistors.

The gate structure 160 may cover the active fin FA of the active region 105. A channel region of each of the transistors may be formed in the active fin FA crossing the gate structure 160.

The channel region may include at least one of a carbon (C) element or an oxygen (O) element, included in a protective layer 103. The channel region may include impurities in an etch stop layer 102 included in a high concentration. According to an example embodiment, the channel region may include boron (B).

Unlike FIG. 2B, a first concentration C₁ of a first element and a second concentration C₂ of a second element may have a continuously decreasing distribution as shown in FIG. 2C.

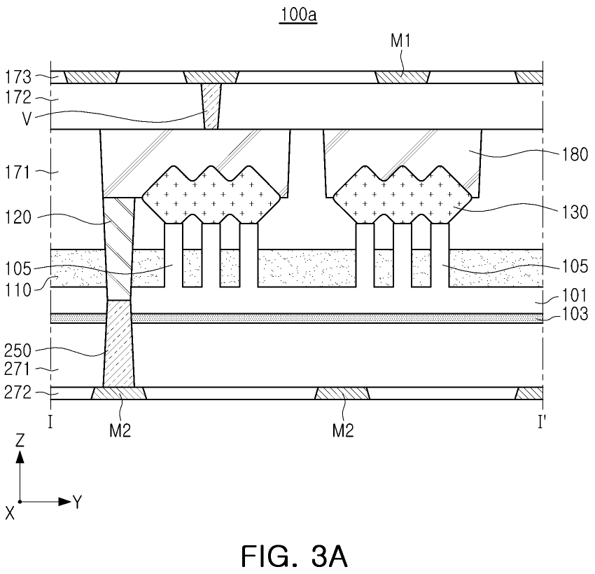

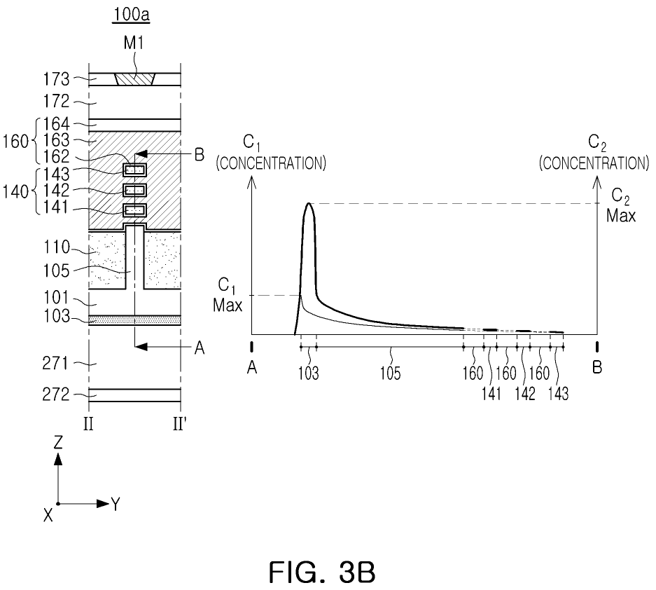

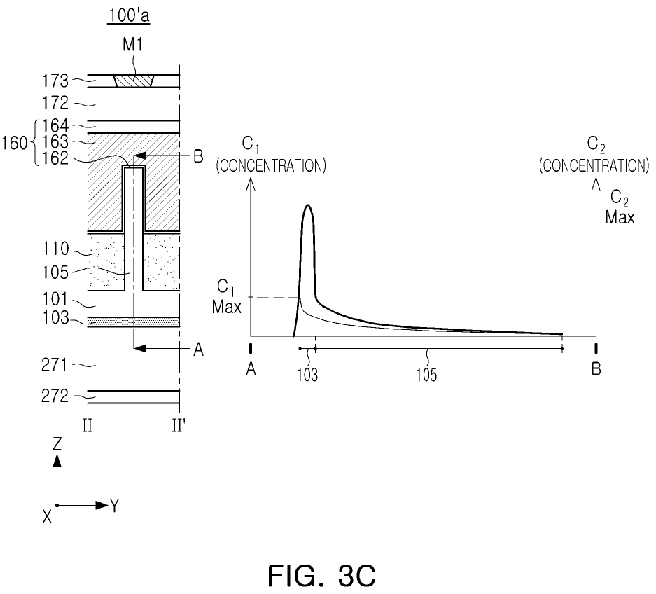

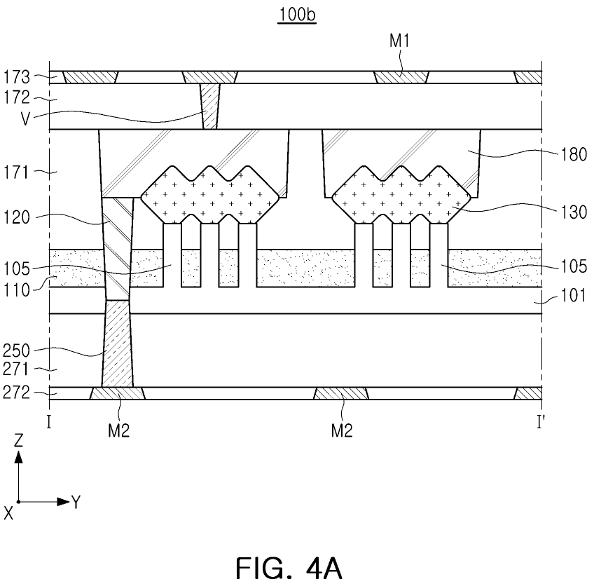

FIG. 3A is a cross-sectional view illustrating a semiconductor device according to example embodiments. FIG. 3A may correspond to a cross-sectional view of the semiconductor device of FIG. 1, taken along line I-I′.

FIG. 3B illustrates concentration distributions of a first element and a second element in a channel region in a semiconductor device according to example embodiments. FIG. 3B may correspond to a cross-sectional view of the semiconductor device of FIG. 1, taken along line II-II′, and illustrates distributions of a first concentration C₁ of the first element and a second concentration C₂ of the second element in a protective layer 103, an active region 105, and a plurality of channel layers 141, 142, and 143, taken along line A-B.

Referring to FIGS. 3A and 3B, an etch stop layer 102 may be removed from a semiconductor device 100a. Therefore, a first lower interlayer insulating layer 271 may be disposed on a lower surface of a protective layer 103 without an intervening etch stop layer. For example, the first lower interlayer insulating layer 271 may contact the lower surface of the protective layer 103. A first concentration C₁ of a first element may decrease from the protective layer 103 toward an upper portion in a plurality of channel layers 141, 142, and 143. According to an example embodiment, the first element may not be measurable in a gate structure 160 between the plurality of channel layers 141, 142, and 143. A second concentration C₂ of a second element may have a distribution, as illustrated in FIG. 3B.

FIG. 3C illustrates concentration distributions of a first element and a second element in a channel region in a semiconductor device according to example embodiments. FIG. 3C may correspond to a cross-sectional view of the semiconductor device of FIG. 1, taken along line II-II′, and illustrates distributions of a first concentration C₁ of the first element and a second concentration C₂ of the second element in a protective layer 103, and an active region 105, taken along line A-B.

Referring to FIGS. 1 and 3C, a semiconductor device 100′a may include FinFET devices in which an active region 105 is a transistor having a fin structure. A first concentration C₁ of a first element may decrease from a protective layer 103 toward an upper portion of a channel region. Unlike FIG. 3B, a second concentration C₂ of a second element may have a continuously decreasing distribution.

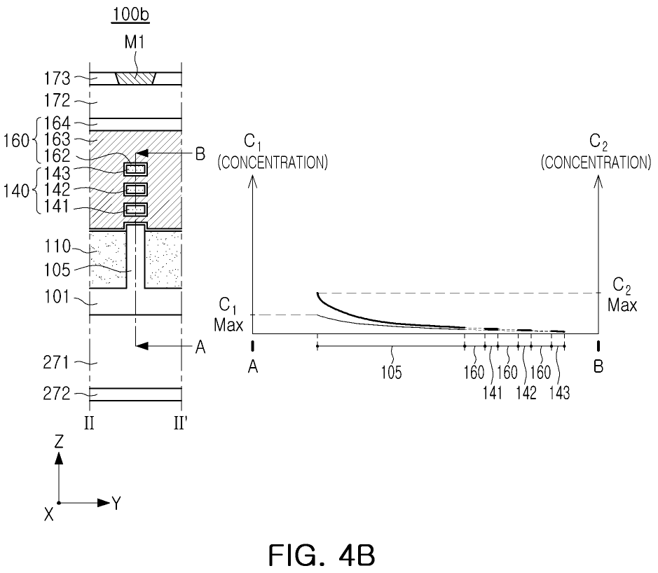

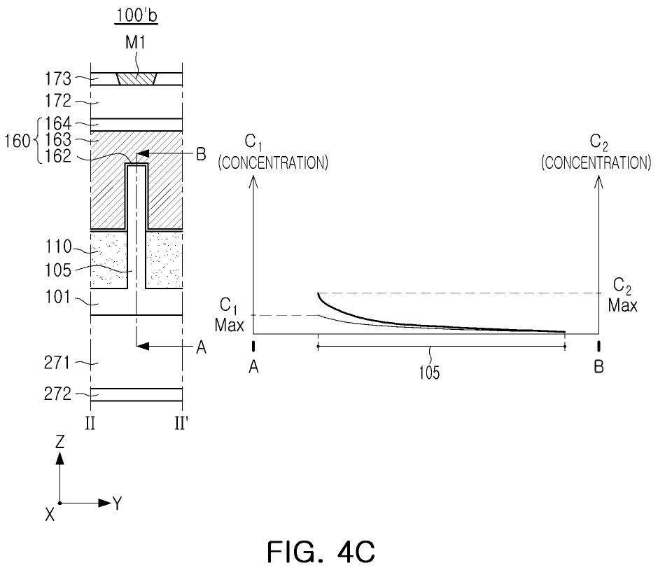

FIG. 4A is a cross-sectional view illustrating a semiconductor device according to example embodiments. FIG. 4A may correspond to a cross-sectional view of the semiconductor device of FIG. 1, taken along line I-I′.

FIG. 4B illustrates concentration distributions of a first element and a second element in a channel region in a semiconductor device according to example embodiments. FIG. 4B may correspond to a cross-sectional view of the semiconductor device of FIG. 1, taken along line II-II′, and illustrates distributions of a first concentration C₁ of the first element and a second concentration C₂ of the second element in an active region 105, taken along line A-B.

Referring to FIGS. 4A and 4B, an etch stop layer 102 and a protective layer 103 may be removed from a semiconductor device 100b. Therefore, a first lower interlayer insulating layer 271 may be disposed on a lower surface of a substrate 101 without an intervening etch stop layer 102 and without an intervening protective layer 103. For example, the first lower interlayer insulating layer 271 may contact the lower surface of the substrate 101. A first concentration C₁ of a first element may decrease from a region in which the substrate 101 and the first lower interlayer insulating layer 271 are in contact with each other toward an upper portion in a plurality of channel layers 141, 142, and 143. A second concentration C₂ of a second element may decrease from a region in which the substrate 101 and the first lower interlayer insulating layer 271 are in contact with each other toward an upper portion of a channel region. According to an example embodiment, the first element and the second element may not be measurable in a gate structure 160 between the plurality of channel layers 141, 142, and 143.

The first concentration C₁ of the first element and the second concentration C₂ of the second element may be at a maximum in a region in which the first lower interlayer insulating layer 271 and the substrate 101 are in contact with each other, and may decrease toward an upper portion of the active region 105 and the upper portion in the plurality of channel layers 141, 142, and 143.

FIG. 4C illustrates concentration distributions of a first element and a second element in a channel region in a semiconductor device according to example embodiments. FIG. 4C may correspond to a cross-sectional view of the semiconductor device of FIG. 1, taken along line II-II′, and illustrates distributions of a first concentration C₁ of the first element and a second concentration C₂ of the second element in an active region 105, taken along line A-B.

Referring to FIG. 4C, a semiconductor device 100′b may include FinFET devices in which an active region 105 is a transistor having a fin structure. A first concentration C₁ of a first element and a second concentration C₂ of a second element may be maximum in a region in which a first lower interlayer insulating layer 271 and a substrate 101 are in contact with each other, and may decrease toward an upper portion of the active region 105.

Unlike FIG. 4B, the first concentration C₁ of the first element and the second concentration C₂ of the second element may have a continuously decreasing distribution.

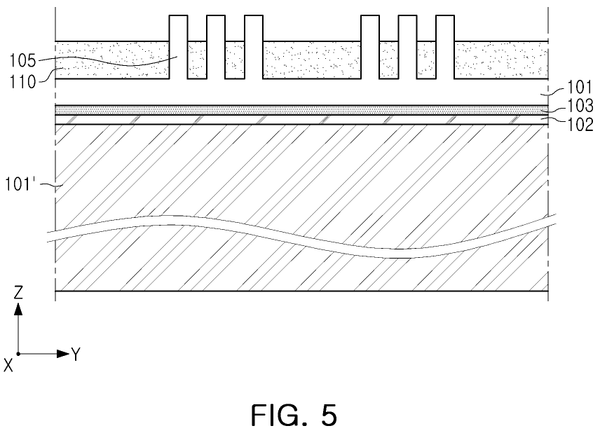

FIGS. 5 to 8 are views illustrating a process sequence to describe a method of manufacturing a semiconductor device according to example embodiments.

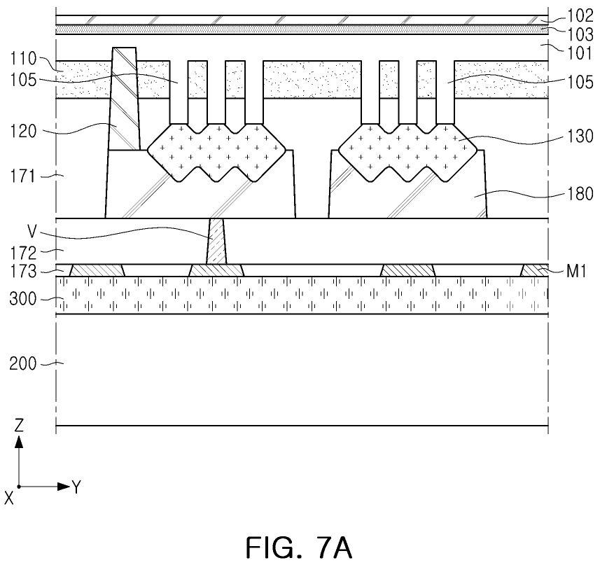

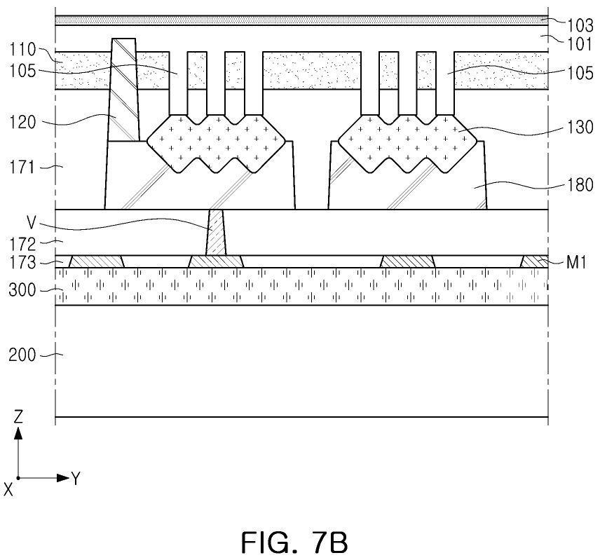

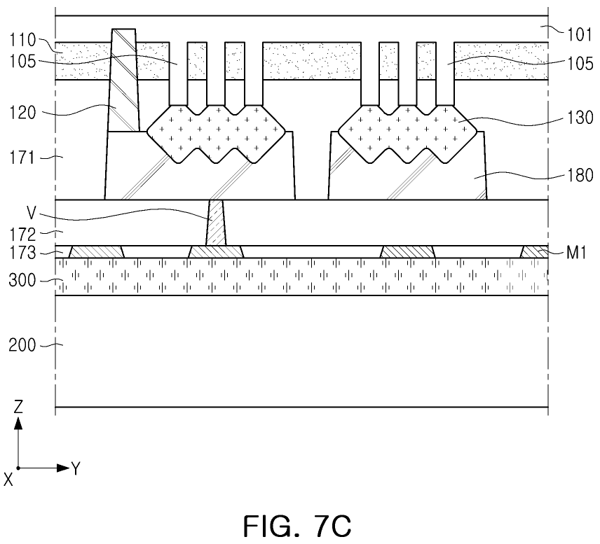

FIG. 5 illustrates a method of manufacturing the semiconductor device 100 of FIG. 2A, FIG. 7B illustrates a method of manufacturing the semiconductor device 100a of FIG. 3A, and FIG. 7C illustrates a method of manufacturing the semiconductor device 100b of FIG. 4A.

Referring to FIG. 5, an etch stop layer 102, a protective layer 103, a substrate 101, an active region 105, and a device isolation layer 110 may be formed on a semiconductor wafer including a base substrate 101′. The base substrate 101′ may be formed of and/or include a semiconductor material, for example, a group IV semiconductor, a group III-V compound semiconductor, or a group II-VI compound semiconductor. According to an example embodiment, the base substrate 101′ may be formed of and/or include silicon or silicon germanium, and may include impurities. For example, at least one of boron (B), gallium (Ga), aluminum (Al), thallium (Tl), or indium (In) may be included. Specifically, the base substrate 101′ may be a P-type substrate doped with boron (B). According to another embodiment, the base substrate 101′ may include undoped (not intentionally doped) silicon. According to another embodiment, the base substrate 101′ may include at least one of phosphorus (P), arsenic (As), or antimony (Sb). In this case, the base substrate 101′ may be an N-type substrate.

The etch stop layer 102 and the protective layer 103 may be formed on the base substrate 101′. The etch stop layer 102 and the protective layer 103 may be formed on the base substrate 101′ by performing an epitaxial growth process. The etch stop layer 102 may be a P+ region in which P-type impurities are doped in a high concentration. The impurity concentration may range about 1×10¹⁹ atoms/cm³ or higher to about 1×10²² atoms/cm³. The etch stop layer 102 may be a highly doped region, as compared to the base substrate 101′, and may thus have etch selectivity with respect to the base substrate 101′. The protective layer 103 may be formed of and/or include silicon (Si) or silicon germanium (SiGe), and may include at least one of a carbon (C) element or an oxygen (O) element. According to an example embodiment, the protective layer 103 may have at least one of SiC or SiO. For example, the protective layer 103 may serve as a diffusion barrier preventing diffusion of a first element into the active region 105 and a plurality of channel layers 141, 142, and 143. Thus, the protective layer 103 may prevent impurities heavily doped in the etch stop layer 102 from diffusing into the substrate 101 or the like.

The substrate 101, the active region 105, and the device isolation layer 110 may be formed on the protective layer 103. According to an example embodiment, the substrate 101 may be formed on the protective layer 103 by performing an epitaxial growth process. Sacrificial layers and the plurality of channel layers 141, 142, and 143 (see FIG. 2B) alternately stacked with the sacrificial layers may be formed on the substrate 101. The active region 105 may be formed to protrude upward from an upper surface of the substrate 101 by removing portions of the sacrificial layers, portions of the plurality of channel layers 141, 142, and 143, and a portion of the substrate 101. In some embodiments, the active region 105 may be part of the substrate 101 (e.g., formed by etching the substrate 101) or may be formed on the substrate 101 (e.g., an epitaxial layer grown from the substrate 101). The active regions 105 may be formed to have a linear shape extending lengthwise in one direction, for example, the X-direction, and may be spaced apart from each other in a second direction that intersects the first direction, for example, the Y-direction. The device isolation layers 110 may be formed in a region in which a portion of the substrate 101 may be removed by burying an insulating material and then recessing the same so that the active region 105 protrudes upwards from the device isolation layer 110. Upper surfaces of the device isolation layers 110 may be formed to be lower than an upper surface of the active region 105.

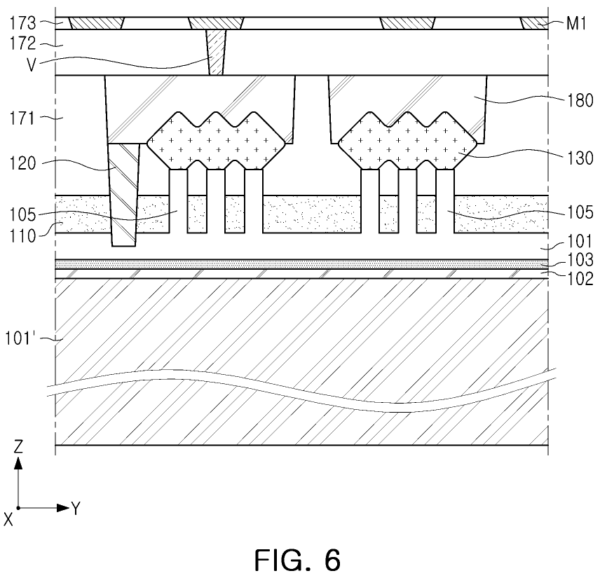

Referring to FIG. 6, by a front end of line (FEOL) process, source/drain regions 130 including an epitaxial layer, a buried conductive structure 120, a contact structure 180, a via V, and a first interconnection portion M1 may be formed on the active regions 105. During the process as described above, impurities of the etch stop layer 102 may diffuse into the protective layer 103, the substrate 101, the active region 105, or the like. Elements included in the protective layer 103 may also diffuse into the substrate 101, the active region 105, or the like. According to an example embodiment, boron (B), carbon (C), oxygen (O), or the like may be diffused. Concentrations of boron (B), carbon (C), and oxygen (O) in the etch stop layer 102, the protective layer 103, the substrate 101, the active region 105, or the like may be compared by a time-of-flight secondary ion mass spectrometry (ToF-SIMS).

Referring to FIG. 7A, to remove the base substrate 101′, a dummy substrate 200 may be attached to the first interconnection portion M1 using an adhesive layer 300. After attaching the dummy substrate 200, the base substrate 101′ may be reversed in a vertical direction (e.g., inverted). A portion of the base substrate 101′ may be removed by a grinding process or a chemical mechanical polishing (CMP) process, and the base substrate 101′ may be entirely removed by performing an anisotropic etching process or an isotropic etching process. According to an example embodiment, after the grinding process, the base substrate 101′ may be removed by a wet etching process. A solution used for wet etching may include an ammonia deionized mixture (ADM) solution, but is not limited thereto. When the wet etching process is performed, the etch stop layer 102 may be a highly doped region, as compared to the base substrate 101′, and may thus have etch selectivity with respect to the base substrate 101′. Therefore, it is possible to reduce a level difference on a surface of the base substrate 101′ that occurs when a conventional base substrate 101′ is removed. For example, since a with-in-wafer (WiW) thickness variation may be reduced, occurrence of defects of a power transmission structure 250 occurring in a subsequent process may be prevented.

Referring to FIG. 7B, unlike FIG. 7A, the etch stop layer 102 may be removed together with a base substrate 101′.

Referring to FIG. 7C, unlike FIGS. 7A and 7B, the protective layer 103 may be removed together with a base substrate 101′ and an etch stop layer 102.

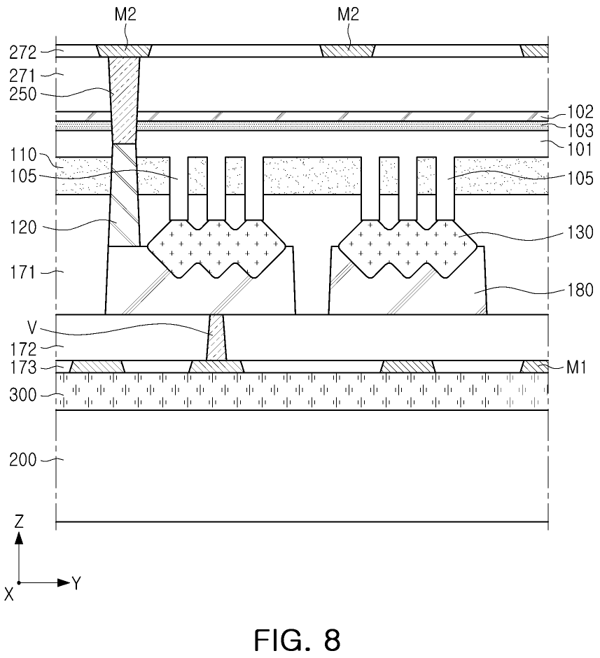

Referring to FIG. 8, a first lower interlayer insulating layer 271, a power transmission structure 250, a second lower interlayer insulating layer 272, and a second interconnection portion M2 may be formed on an etch stop layer 102. However, this is only illustrative for a process of preparing the semiconductor device 100 of FIG. 2A. In the semiconductor device 100a of FIG. 3A, during the process of FIG. 7B, an etch stop layer 102 may be removed, and a first lower interlayer insulating layer 271 or the like may be formed on a protective layer 103. In the semiconductor device 100b of FIG. 3B, during the process of FIG. 7C, an etch stop layer 102 and a protective layer 103 may be removed, and a first lower interlayer insulating layer 271 or the like may be formed on a substrate 101. The power transmission structure 250 is illustrated to be connected to a buried conductive structure 120 in a substrate 101, but is not limited thereto, and may be connected to each other in a device isolation layer 110.

Referring to FIG. 2A together, the adhesive layer 300 and the dummy substrate 200 may be removed to provide the semiconductor device 100. By the process as described above, it is possible to improve flatness of a wafer provided as the base substrate 101′ or the like, and reduce a WiW total thickness variation (TTV) representing a difference between maximum and minimum thicknesses of the wafer. As a result, a semiconductor device 100 having an improved profile of a power transmission structure 250 and the like and improved electrical characteristics may be provided.

In a process of forming a semiconductor device, a variation in a with-in-wafer (WIW) thickness may be reduced by an etch stop layer disposed on a lower surface of a substrate, and diffusion of elements included in the etch stop layer by a protective layer may be prevented, to provide a semiconductor device having improved electrical characteristics.

Various advantages and effects of the present inventive concept are not limited to the above, and will be more easily understood in the process of describing specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate;
an active region extending on the substrate in a first direction;
a protective layer on a lower surface of the substrate;
an etch stop layer on a lower surface of the protective layer;
a device isolation layer defining the active region;
a gate structure on the active region and extending in a second direction intersecting the first direction;
a source/drain region on the active region on both lateral sides of the gate structure;
a contact structure connected to the source/drain region; and
a power transmission structure electrically connected to the contact structure.

2. The semiconductor device of claim 1, wherein the protective layer comprises at least one of silicon (Si) or silicon germanium (SiGe), and at least one of a carbon (C) element or an oxygen (O) element.

3. The semiconductor device of claim 1, wherein the etch stop layer comprises impurities in a concentration ranging from about 1×10¹⁹ atoms/cm³ or higher to about 1×10²² atoms/cm³.

4. The semiconductor device of claim 3, wherein the impurities comprise at least one of phosphorus (P), arsenic (As), antimony (Sb), boron (B), gallium (Ga), aluminum (Al), thallium (Tl), or indium (In).

5. The semiconductor device of claim 1, wherein the etch stop layer includes at least one of silicon (Si) or silicon germanium (SiGe) and at least one of a group 13 element or a group 15 element of the periodic table of elements.

6. The semiconductor device of claim 1, further comprising a buried conductive structure connected to the contact structure and passing through the device isolation layer,
wherein the power transmission structure passes through the protective layer and the etch stop layer.

7. The semiconductor device of claim 1, further comprising a lower interlayer insulating layer on a lower surface of the etch stop layer.

8. The semiconductor device of claim 7, wherein the etch stop layer is between the protective layer and the lower interlayer insulating layer.

9. The semiconductor device of claim 8, wherein the power transmission structure passes through the lower interlayer insulating layer.

10. The semiconductor device of claim 1, wherein the active region comprises a base active region and at least one active fin,
wherein the at least one active fin protrudes from the base active region and extends in the first direction.

11. The semiconductor device of claim 10, further comprising a plurality of channel layers that are spaced apart in a third direction substantially perpendicular to a major surface of the substrate from one another and at least one active fin and surrounded by the gate structure.

12. The semiconductor device of claim 11, wherein at least a portion of the plurality of channel layers comprise at least one of a carbon (C) element or an oxygen (O) element,
wherein a concentration of the at least one carbon (C) element or oxygen (O) element decreases toward an upper portion in the plurality of channel layers.

13. A semiconductor device comprising:
a substrate;
an active region extending on the substrate in a first direction;
a plurality of channel layers on the active region spaced apart from each other in a direction perpendicular to an upper surface of the substrate;
a device isolation layer defining the active region;
a gate structure on the active region and extending in a second direction intersecting the first direction;
a source/drain region on the active region on both lateral sides of the gate structure;
a contact structure connected to the source/drain region;
a buried conductive structure connected to the contact structure;
a lower interlayer insulating layer on a lower surface of the substrate; and
a power transmission structure passing through the lower interlayer insulating layer and connected to the buried conductive structure,
wherein at least a portion of the active region and the plurality of channel layers includes a group 13 element or a group 15 element of the periodic table of elements in a first concentration, and
at least a portion of the active region and the plurality of channel layers includes at least one of a carbon (C) element or an oxygen (O) element in a second concentration.

14. The semiconductor device of claim 13, wherein the second concentration is higher than the first concentration.

15. The semiconductor device of claim 13, wherein the first concentration and the second concentration are at a maximum in a region in which the lower interlayer insulating layer and the substrate are in contact with each other, and decrease toward an upper portion of the active region and an upper portion in the plurality of channel layers.

16. The semiconductor device of claim 13, further comprising a protective layer between the substrate and the lower interlayer insulating layer and including at least one of SiC or SiO.

17. The semiconductor device of claim 16, wherein a concentration of the carbon (C) element or a concentration of the oxygen (O) element in the protective layer is higher than a concentration of the carbon (C) element or the oxygen (O) element in the active region and the plurality of channel layers.

18. The semiconductor device of claim 16, further comprising:
an etch stop layer between the protective layer and the lower interlayer insulating layer,
wherein the etch stop layer includes impurities in a concentration ranging from about 1×10¹⁹ atoms/cm³ or higher to about 1×10²² atoms/cm³.

19. The semiconductor device of claim 18, wherein the impurities comprise boron (B).

20. A semiconductor device comprising:
a substrate;
an active region extending on the substrate in a first direction;
a protective layer on a lower surface of the substrate, including at least one of silicon (Si) or silicon germanium (SiGe), and at least one of a carbon (C) element or an oxygen (O) element;
a device isolation layer defining the active region;
a gate structure on the active region and extending in a second direction intersecting the first direction;
a source/drain region on the active region on both lateral sides of the gate structure;
a contact structure connected to the source/drain region; and
a power transmission structure electrically connected to the contact structure,
wherein the active region includes at least one of the carbon (C) element or the oxygen (O) element, and
a concentration of the carbon (C) element or a concentration of the oxygen (O) element in the protective layer is higher than a concentration of the carbon (C) element or the oxygen (O) element in the active region.
